(19) United States
(12) Patent Application Publication
(10) Pub. No.: US 2020/0105345 A1
(43) Pub. Date: Apr. 2, 2020

(54) LEAKAGE CURRENT COMPENSATION DEVICE AND SEMICONDUCTOR MEMORY DEVICE

(71) Applicant: SAMSUNG ELECTRONICS CO., LTD., Suwon-si (KR)

(72) Inventors: JONG MIN BAEK, Hwaseong-si (KR); VIVEK VENKATA KALLURU, Suwon-si (KR); JONG RYUL KIM, Dangjin-si (KR); BILAL AHMAD JANJUA, Suwon-si (KR)

(21) Appl. No.: 16/384,381

(22) Filed: Apr. 15, 2019

(30) Foreign Application Priority Data
Oct. 2, 2018 (KR) 10-2018-0117301

(51) Int. Cl. G11C 13/00

(52) U.S. Cl. CPC G11C 13/0033; G11C 13/004; G11C 13/0038

(57) ABSTRACT

A leakage current compensation device includes a current supply unit configured to supply a current to at least one operating cell, among a plurality of cells of a memory device disposed at intersections of wordlines and bitlines, a leakage current sensing unit configured to sense an amount of leakage current flowing to a non-operating cell among the cells to output a result value based on the sensed amount of leakage current, and a compensation current supply unit configured to receive the result value and supply a compensation current to the operating cell.

### CROSS-REFERENCE TO RELATED APPLICATION(S)

This U.S. non-provisional application claims priority to and the benefit Korean Patent Application No. 10-2018-0117301 filed on Oct. 2, 2018 in the Korean Intellectual Property Office, the disclosure of which is incorporated by reference in its entirety herein.

### BACKGROUND

### 1. Technical Field

The present inventive concept relates to a leakage current compensation device and a semiconductor memory device, and more particularly, to a leakage current compensation device for adaptively compensating for a leakage current and a semiconductor memory device including the leakage current compensation device.

### 2. Discussion of Related Art

Semiconductor memory devices include volatile memory devices, such as a dynamic random access memory (DRAM), and nonvolatile memory devices such as a magnetic random access memory (MRAM), a ferroelectric random access memory (FRAM), a phase-change random access memory (PRAM), a resistance random access memory (RRAM), and the like.

Such a semiconductor memory includes a large number of memory cells connected to one another. Such memory cells are disposed at intersections of a plurality of wordlines and a plurality of bitlines. Reading, writing, and/or erasing operations may be performed on such memory cells. In the case of a writing operation, a current flowing to a target cell of the writing operation needs to be controlled so that the target cell is written with the correct data.

### SUMMARY

At least one exemplary embodiment of the present inventive concept provides a leakage current compensation device to prevent a situation in which a sufficient current does not flow to an operating cell due to a leakage current flowing through other cells and/or bitlines. The leakage current is generated when an operation is performed on the operating cell among a plurality of cells present in a semiconductor memory device. The leakage current compensation device may be located within the semiconductor memory device.

According to an exemplary embodiment of the present inventive concept, a leakage current compensation device includes a current supply unit configured to supply a current to at least one operating cell, among a plurality of cells of a memory device disposed at intersections of wordlines and bitlines, a leakage current sensing unit configured to sense an amount of leakage current flowing to a non-operating cell among the cells to output a result value based on the sensed amount of leakage current, and a compensation current supply unit configured to receive the result value and supply a compensation current to the operating cell.

According to an exemplary embodiment of the present inventive concept, a leakage current compensation device includes a current supply unit configured to supply a current to at least one operating cell, among a plurality of cells of a memory device disposed at intersections of wordlines and bitlines and a leakage current compensation unit configured to sense an amount of leakage current flowing to a non-operating cell among the cells during a sampling period before an operating period to determine a result value based on the sensed amount of leakage current and to supply a compensation current to the operating cell based on the result value during the operating period.

According to an exemplary embodiment of the present inventive concept, a semiconductor memory device includes a plurality of memory cells disposed at intersections of a plurality of wordlines and a plurality of bitlines, a current supply unit connected to one end of at least one wordline among the plurality of wordlines to supply a current to at least one operating cell among the plurality of memory cells, and a leakage current compensation unit configured to sense an amount of leakage current flowing to a non-operating cell of the memory cells to supply a compensation current to the operating cell according to the sensed amount of leakage current.

### BRIEF DESCRIPTION OF DRAWINGS

Embodiments of the present disclosure will be more clearly understood from the following detailed description, taken in conjunction with the accompanying drawings, in which:

FIG. 1 is a schematic diagram illustrating an arrangement of memory cells in a semiconductor memory;

FIG. 2 is a schematic diagram illustrating a case in which a current is supplied to a cell distant from a current source in a semiconductor memory;

FIG. 3 is a schematic diagram illustrating a case in which a current is supplied to a cell near a current source in a semiconductor memory;

FIG. 4 is a schematic diagram illustrating a relationship between a location of a memory cell and the amount of leakage current in a semiconductor memory;

FIG. 5 is a block diagram of a leakage current compensation device according to an exemplary embodiment of the present inventive concept;

FIG. 6 is a circuit diagram illustrating a simplified circuit configuration of a leakage current compensation device according to an exemplary embodiment of the present inventive concept;

FIGS. 7A and 7B are graphs illustrating a leakage current compensation operation according to the exemplary embodiment illustrated in FIG. 6;

FIG. 8 is a circuit diagram illustrating that one or more sense amplifiers used in at least one exemplary embodiment of the present inventive concept are applied during a reading operation;

FIG. 9 is a circuit diagram illustrating a circuit configuration of a leakage current compensation device according to an exemplary embodiment of the present inventive concept;

FIG. 10 is a circuit diagram illustrating a circuit configuration of a leakage current compensation device according to an exemplary embodiment of the present inventive concept;

FIG. 11 is a block diagram of a leakage current compensation device according to an exemplary embodiment of the present inventive concept;

FIG. 12 is a circuit diagram illustrating a circuit configuration of a leakage current compensation device according to an exemplary embodiment of the present inventive concept; and

FIG. 13 is a graph illustrating an operation of the exemplary embodiment illustrated in FIG. 12.

### DETAILED DESCRIPTION OF THE EXEMPLARY EMBODIMENTS

Hereinafter, exemplary embodiments of the present inventive concept will be described with reference to the accompanying drawings

The present inventive concept will become apparent from the detailed description of the following embodiments, taken in conjunction with the accompanying drawings. It should be understood that the present inventive concept is not limited to the following embodiments and may be embodied in different ways, and that the embodiments are provided for complete disclosure and to aid those skilled in the art in understanding the present invention. Like components will be denoted by like reference numerals throughout the specification.

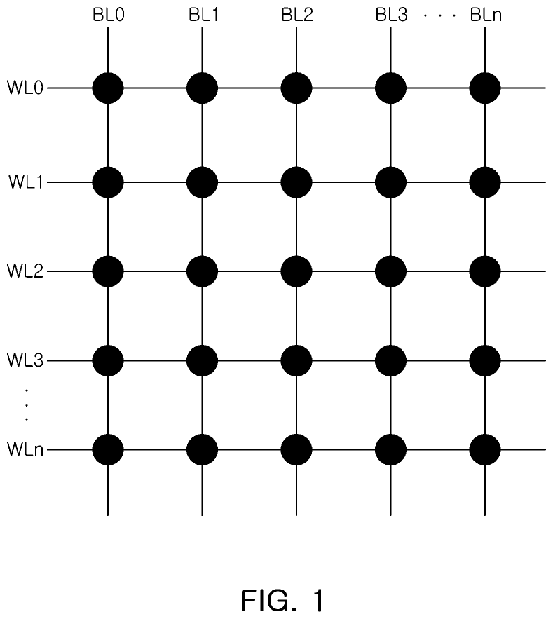

FIG. 1 is a schematic diagram illustrating an arrangement of memory cells in a semiconductor memory. A semiconductor memory includes a large number of memory cells connected to one another.

As illustrated in FIG. 1, the memory cells are disposed at intersections of a plurality of wordlines (e.g., WL0, WL1, WL2, WL3, . . . , WLn) and a plurality of bitlines (e.g., BL0, BL1, BL2, BL3, . . . , BLn). To perform reading, writing, erasing operations, or the like, on a specific cell among the memory cells, an appropriate amount of current needs to be supplied to a corresponding cell.

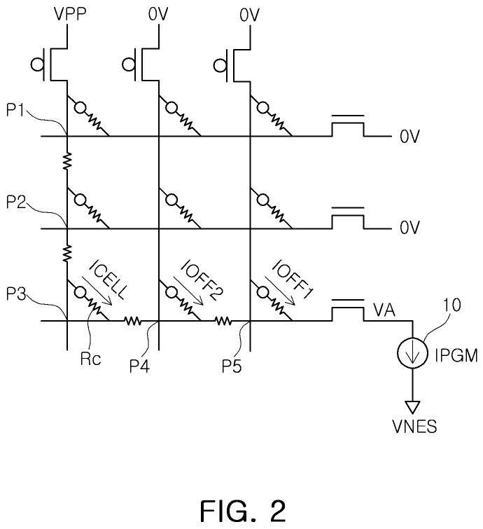

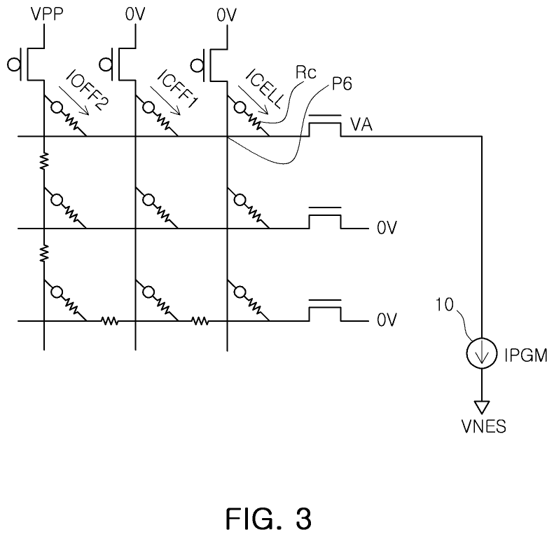

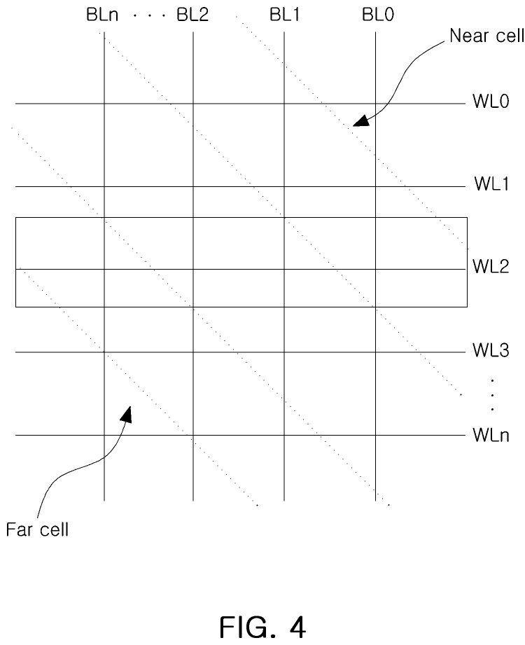

FIG. 2 is a schematic diagram illustrating a case in which a current is supplied to a cell distant from a current source in a semiconductor memory, FIG. 3 is a schematic diagram illustrating a case in which a current is supplied to a cell near a current source in a semiconductor memory, and FIG. 4 is a schematic diagram illustrating a relationship between a location of a memory cell and the amount of leakage current in a semiconductor memory.

FIG. 2 illustrates a case in which a current is supplied to a memory cell relatively distant from a current source, among intersections of a plurality of wordlines and a plurality of bitlines. A voltage VPP is applied to a bitline, passing through an intersection P3, to operate a memory cell disposed at the intersection P3. A current flows through a path of intersections P1, P2, P3, P4, and P5, through driving of a current source 10. It is ideal that the current does not flow to other bitlines and wordlines unassociated with a memory cell to be driven.

However, parasitic resistance present on a line between each intersection and each intersection causes a voltage drop while a current flows. As a voltage occurs due to parasitic resistance while a current flows through the path of intersections P1, P2, P3, P4, and P5, a voltage applied to one end VA of the current source 10 may have a value significantly lower than a value of 0 volt. Similarly, voltages applied to the intersections P3, P4, and P5 have values greater than a value of the voltage applied to the VA, but the values thereof are significantly smaller than the value of 0 volt. Accordingly, unnecessary leakage currents IOFF1 and IOFF2 flow to a bitline passing through the intersection P4 and a bitline passing through the intersection P5. As a result, the current supplied through the current source 10 does not directly flow to memory cells present at the intersection P3 while maintaining a magnitude thereof. Instead, a current ICELL having a magnitude decreased by the amount of leakage currents IOFF1 and IOFF2 flows to a memory cell present at the intersection P3, and thus, a current having an amount smaller than an intended amount is supplied to an operating cell.

When a memory cell to operate is disposed at a location distant from the current source 10, the number of current paths is increased. Thus, the degree of voltage drop is increased to cause a great difference between a voltage value of an intersection on a wordline passing through a long distance cell and the value of 0 volt. As a result, values of the leakage current IOFF1 flowing to a bitline passing through the intersection P4 and the leakage current IOFF2 flowing to a bitline passing through the intersection P5 are also increased. Due to the leakage currents IOFF1 and IOFF2, a current ICELL flowing to a driving cell may have a value significantly lower than a value of a supply current IPGM of the current source 10. In addition, since the voltage drop further occurs due to the parasitic resistance present between the intersections P4 and P5 while a current passes through the intersections P4 and P5, the leakage current IOFF1 may have a value larger than the value of the leakage current IOFF2.

On the other hand, referring to FIG. 3, when a memory cell present at a relatively short distance from the current source 10, for example, the intersection P6, is driven, a possibility of being affected by parasitic resistance on a bitline or a wordline is reduced because a current flow path is short. Accordingly, since the voltage drop rarely occurs, the leakage currents IOFF1 and IOFF2 may be significantly small or negligible.

As set forth with reference to FIGS. 2 and 3, the amount of a leakage current generated may vary depending on a location of a memory cell on a semiconductor memory. A near cell refers to a cell having a short distance from the current source 10 configured to supply a current through a wordline. More specifically, a near cell refers to a cell in which a significantly less leakage current is generated, as illustrated in FIG. 3, because a flow path of a current supplied to an operating cell is short. Meanwhile, a far cell refers to a cell having a long distance from the current source 10. More specifically, a far cell refers to a cell in which more leakage current is generated, as illustrated in FIG. 2, because a flow path of a current supplied to an operating cell is long.

In an exemplary embodiment, the resistor Rc illustrated in FIG. 2 and FIG. 3 represents a resistive material of a resistive memory cell. As shown in FIG. 2 and FIG. 3, the current source 10 may be located between an end of a wordline and a ground voltage VNES.

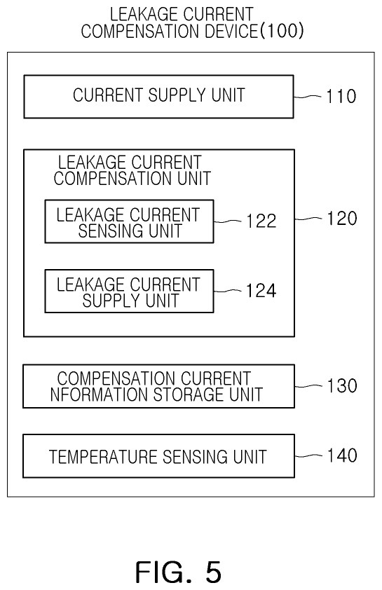

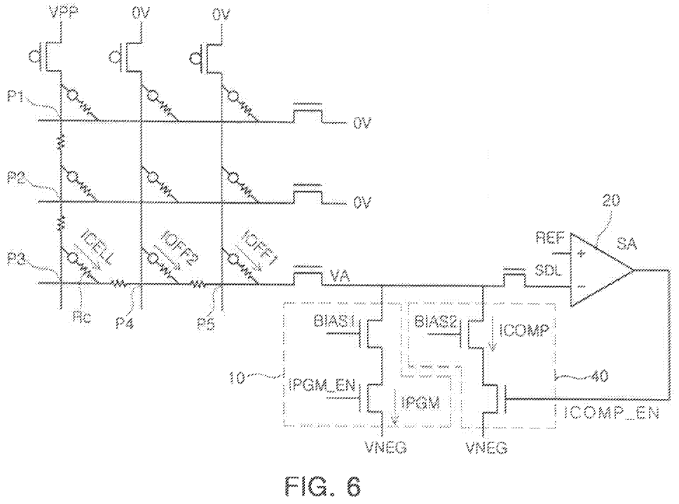

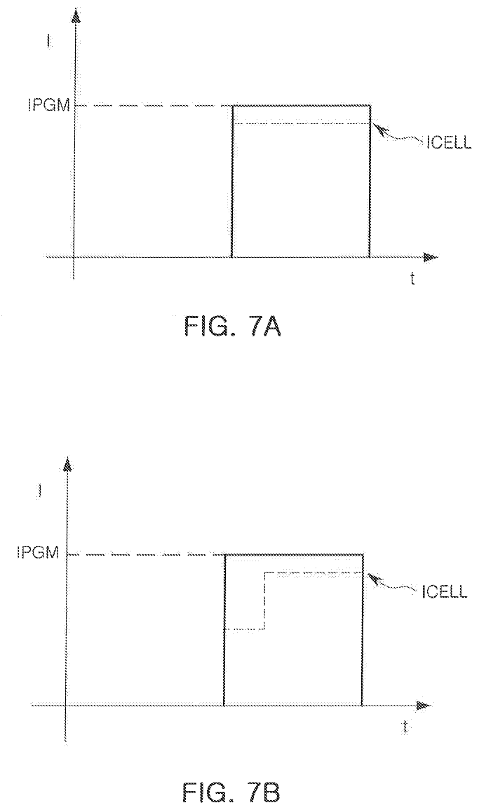

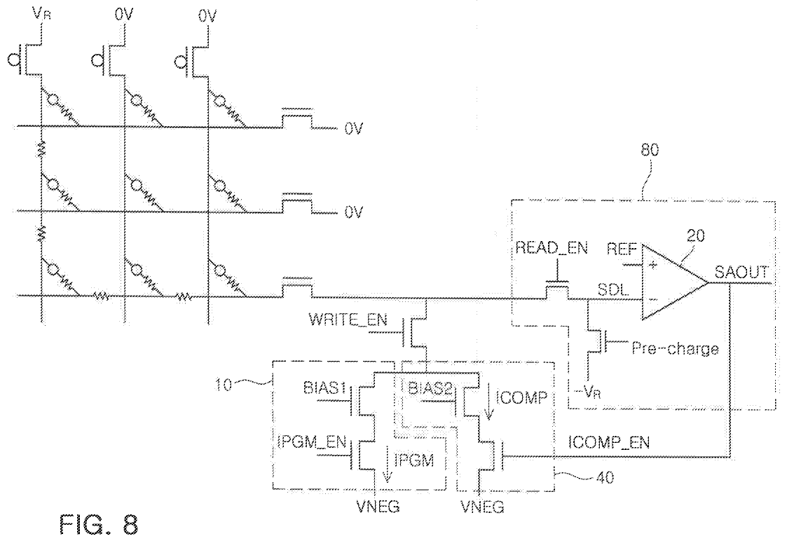

FIG. 5 is a block diagram of a leakage current compensation device according to an exemplary embodiment of the present inventive concept, and FIG. 6 is a circuit diagram illustrating a simplified circuit configuration of a leakage current compensation device according to an exemplary embodiment of the present inventive concept. FIGS. 7A and 7B are graphs illustrating a leakage current compensation operation according to the exemplary embodiment illustrated in FIG. 6. FIG. 8 is a circuit diagram illustrating that one or more sense amplifiers used in at least one exemplary embodiment of the present inventive concept are applied during a read operation.

A leakage current compensation device 100 according to an exemplary embodiment includes a current supply unit 110 (e.g., a current supply) and a leakage current compensation unit 120 (e.g., a circuit). In an exemplary embodiment, the leakage current compensation unit 120 includes a leakage current sensing unit 122 (e.g., a circuit) and a compensation current supply unit 124 (e.g., a current supply).

A current supply unit 110 supplies a current to at least one or more memory cells among a plurality of cells disposed at intersections of wordlines and bitlines. The current supply unit 110 may be connected to each wordline. In an exemplary embodiment illustrated in FIG. 6, the current supply unit 110 is a transistor 10 conducting a programmable current IPGM in response to an input signal IPGM_EN, but is not limited thereto. Since a current is supplied to a memory cell at a specific moment to operate a corresponding memory cell, a memory cell to be supplied with a current will be referred to as an “operating cell”, while cells other than the operating cell will be referred to “non-operating cells” for ease of description.

The leakage current sensing unit 122 senses the amount of a leakage current flowing to a non-operating cell other than an operating cell to output a result value depending on the amount of the sensed leakage current. In the circuit illustrated in FIG. 6, a manner of measuring a voltage value at one end SDL of the current supply unit 110 may be applied as an example of sensing the amount of a leakage current. For example, as the amount of leakage current increases, the degree of voltage drop increases while a current flows to bitlines and wordlines. Therefore, it is determined that the smaller the voltage value at the one end SDL of the current supply unit 110, the more the amount of leakage current.

To this end, the leakage current sensing unit 122 may include a first sense amplifier (SA) 20 configured to sense the voltage value at the one end SDL of the current supply unit 110. In an exemplary embodiment, when the amount of leakage current is higher than a reference value (REF), it is determined that a compensation current will be supplied. For example, this technique may be applied to the exemplary embodiment illustrated in FIG. 6. In this case, a voltage value at the one end SDL of the current supply units 110 and 10 is provided to a first input terminal of the first sense amplifier 20, a first reference voltage REF is provided to a second input terminal of the first sense amplifier 20, and the first sense amplifier 20 compares a voltage value at one end of the current supply units 110 and 10 with the first reference voltage REF to output a result value varying depending on a comparison result.

In the present embodiment, the first sense amplifier 20, suggested as an example of the leakage current sensing unit 122, may be an amplifier that is already present in a semiconductor memory device. For example, in the case in which an amplifier involved not in a writing operation but in only a read operation is already present in a semiconductor memory device, the corresponding amplifier may be used as the first sense amplifier 20. As illustrated in FIG. 8, the sense amplifier 20 may be an amplifier that is originally involved in a read operation in a semiconductor memory device. In the present disclosure, since an existing amplifier used for other purposes may be used to sense a leakage current, it is unnecessary to additionally mount a new amplifier for sensing a leakage current. For example, in FIG. 8, the sense amplifier 20 is involved in a read operation when a signal READ_EN is in an ON state, but is used to sense information on the amount of leakage current generated during a writing operation when a signal WRITE_EN is in an ON state. In an embodiment, the signal READ_EN and signal WRITE_EN are not both in the ON state at the same time. For example, when the signal READ_EN is in an ON state during a read operation, the signal WRITE_EN is in an OFF state. For example, when the signal WRITE_EN is in an ON state during a write operation, the signal READ_EN is in an OFF state. The circuit of FIG. 8 may include a write enable transistor connected between a word line and the current supply unit 124 whose gate terminal receives the write enable signal WRITE_EN. In an embodiment, the circuit of FIG. 8 includes a sensing circuit 80 that includes the sense amplifier 20 outputting a result value SAOUT, a read enable transistor whose gate terminal receives the read enable signal READ_EN, and pre-charging transistor whose gate terminal receives a pre-charging signal Pre-charge. The read enable transistor may be connected between an end of a wordline and the second input terminal of the sense amplifier 20. In an embodiment, the pre-charging transistor is connected between one end SDL of the current supply unit 110 and a negative voltage −V_{R}.

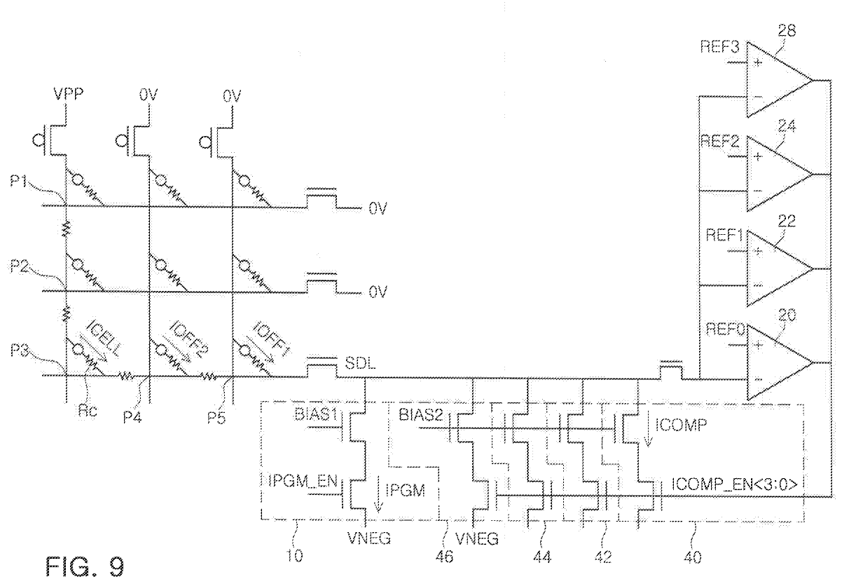

Although only one sense amplifier 20 has been described in FIG. 8, one or more sense amplifiers 20, 22, 24, and 28 illustrated in FIG. 9 are similar to the sense amplifier 20. A plurality of such amplifiers are also involved in a read operation, but may be used to sense a leakage current during a writing operation.

The compensation current supply unit 124 receives the result value output by the leakage current sensing unit 122 and supplies a compensation current to an operating cell. For example, in the embodiment illustrated in FIG. 6, the compensation current supply unit 124 is implemented using a transistor 40 conducting a compensation current ICOMP in response to a result value ICOMP_EN output by the leakage current sensing units 122 (or the sense amplifier 20). However, embodiments of the compensation current supply unit 124 are not limited to use of transistor 40.

In FIG. 6 and FIGS. 9 and 11, an example of the leakage current compensation device 100 according to the present disclosure is shown as being provided on only one of a plurality of wordlines, for ease of description and for brevity of illustration. However, the leakage current compensation device 100 according to the present disclosure may be provided on several of the plurality of wordlines. For example, the leakage current compensation device 100 may only be provided on wordlines including arbitrary far cells, or may be provided on all the wordlines.

Hereinafter, operation of the leakage current compensation device 100 according to an exemplary embodiment of the present disclosure will be described in detail with reference to FIGS. 6, 7A, and 7B. In FIG. 6, it is assumed that the first reference voltage REF is preset to a specific value. The amount of leakage current in the case, in which a memory cell disposed relatively closely to the current supply units 110 and 10 in intersections present on a specific wordline connected to the leakage current compensation device 100 is an operating cell, may be smaller than the amount of leakage current in the case in which a memory cell disposed relatively distant from the current supply units 110 and 10. When a voltage value at a point of one end SLD of the current supply units 110 and 10 is greater than a predetermined specific value, it is determined that a voltage drop at the SLD point occurs to some extent due to the leakage current, but is not enough to compensate for a current. FIG. 7A is a graph illustrating a case in which the compensation current supply unit 124 does not further supply a compensation current to an operating cell because the amount of leakage current is so small that there is no need to compensate for the current.

Meanwhile, the amount of leakage current, in which a memory cell disposed relatively distant from the current supply units 110 and 10 connected to the leakage current compensation device 100 in the intersections present on a specific wordline is an operating cell, may be greater than the amount of leakage current in which a memory cell disposed relatively near the current supply units 110 and 10 is an operation cell. Accordingly, in the case in which the voltage value at the one end SLD of the current supply units 110 and 10 is less than a predetermined specific value, the amount of leakage current is large, and thus, a large voltage drop at the SLD point occurs. As a result, it may be determined that there is a need to supply a compensation current ICOMP to the operating cell according to the amount of leaked current.

In this case, a criterion of determining compensation for the current may be determined as necessary, and a value of the first reference voltage REF is preset depending on the criterion. For example, in the embodiment of FIG. 6, the reference voltage REF may have be a negative value such as −1.5 volts.

In an embodiment, the current supply unit 10 of FIG. 6 includes a first transistor having a gate terminal receiving a first bias signal BIAS1 and a second transistor having a gate terminal receiving the input signal IPGM_EN. In an embodiment, the second transistor of the current supply unit 10 is connected between the first transistor of the current supply unit 10 and a ground voltage VNEG. In an embodiment, the current supply unit 124 includes a first transistor having a gate terminal receiving a second bias signal BIAS2 and a second transistor receiving an output of the sense amplifier 20. In an embodiment, the second transistor of the current supply unit 124 is located between the first transistor of the current supply unit 124 and a ground voltage VNEG.

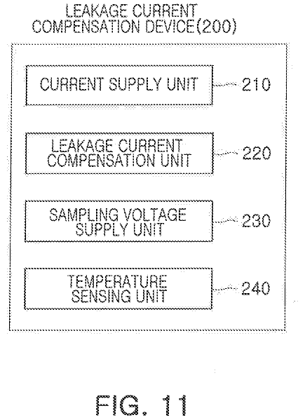

A value of a first reference voltage REF applied to respective leakage current compensation devices 100 connected to respective wordlines may be set differently for each wordline. This causes a boundary value, at which the compensation current ICOMP starts to be supplied for each wordline, to be set differently for each wordline. More specifically, as illustrated in FIG. 6 and will be illustrated in FIGS. 9 and 11, an example of a leakage current compensation device according to the present disclosure is provided on only one of a plurality of wordlines, for ease of description and for brevity of illustration. In the case in which a leakage current compensation device according to the present disclosure is installed in one or more wordlines other than a lowermost wordline in FIG. 6, a value of the reference voltage applied to each wordline may become different. For example, a preset value of the first reference voltage REF is set differently for each wordline.

When the reference voltage value is set differently for each wordline as described above, a current compensation operation starting point depending on a location of an operation cell may be set differently to flexibly supply a flexible compensation current. For example, a value of the reference voltage REF supplied to a leakage current compensation device provided on an upper wordline may be set to be greater than a value of the reference voltage REF supplied to a leakage current compensation device provided on a lowermost wordline. Accordingly, the current compensation operation starting point of the upper wordline, in which a relatively smaller amount of leakage current is expected to be generated as compared to the lower wordline, may be set more sensitively than the current compensation operation starting point of a lower wordline.

Additionally, the reference voltage value supplied to all the leakage current compensation devices provided on the respective wordlines may be generally adjusted depending on a change in temperature of a surrounding environmental element. For example, when a temperature of a semiconductor memory device is increased step by step, the amount of leakage current is increased to increase a probability that the voltage value at one end (SLD) point of the current supply portion 10 is lower than the reference voltage value. Accordingly, a possibility of leakage current compensation may be increased. However, the reference voltage value supplied to the leakage current compensation device provided on each wordline may be changed depending on a temperature variation of the semiconductor memory device to further advance or delay a leakage current compensation starting point depending on a temperature rise, as needed.

FIG. 7A illustrates a case in which a voltage at an SLD point is greater than a first reference voltage REF and current compensation is not performed. FIG. 7B illustrates a case in which a voltage at an SLD point is smaller than a first reference voltage REF, and thus, current compensation is performed. An increment shown by dotted lines in a box on a right side of the graphs in FIG. 7A and FIG. 7B is the amount of compensation current ICOMP further supplied to an operating cell by compensation current supply units 124 and 40.

Returning to FIG. 5, a leakage current compensation device 100 according to an exemplary embodiment may further include a compensation current information storage unit 130 (e.g., a storage device). The compensated current information storage unit 130 stores different compensated current amount information depending on at least one of different temperature intervals and different cell locations.

When the voltage at the SLD point drops below a predetermined first reference voltage REF and the compensation current supply unit 124 supplies a compensation current, the compensation current supply unit 124 supplies different compensation currents to each other. This is because the leakage current may vary depending on a cell location, as described above. Accordingly, the magnitude of a current to be compensated may vary depending on the cell location.

Parasitic resistances present on respective lines (e.g., bitlines or wordlines) are variable depending on a temperature. Assuming that a voltage is equivalently supplied, the amount of leakage current tends to increase when a temperature increases. Thus, the magnitude of the compensation current to be compensated also needs to be determined adaptively depending on temperature variation.

The compensation current information storage unit 130 stores the magnitude of compensation current to be compensated, according to such a cell location and/or a temperature interval as an environmental element, in the form of a look-up table. Thus, the leakage current compensation device 100 according to at least one exemplary embodiment may precisely perform current compensation.

A leakage current compensation device 100 according to an exemplary embodiment may further include a temperature sensing unit 140 (e.g., a temperature sensor or circuit) configured to sense a temperature of a plurality of cells or a surrounding temperature of the plurality of cells in such a manner that the magnitude of the compensation current to be compensated varies depending on a temperature interval as an environmental element. The temperature sensing unit 140 senses a temperature of a semiconductor memory device, in which a plurality of cells are disposed, and transmits the sensed temperature to the compensation current information storage unit 130.

When an environmental element is not taken into account, the compensation current information storage unit 130 may provide a compensation current, depending on a position of a memory cell, to the compensation current supply unit 124. When the environmental element is taken into account, the compensation current information storage unit 130 may determine a compensation current value using a lookup table, previously stored for each temperature interval, based on the temperature information received from the temperature sensing unit 140 and may provide the determined value to the compensation current supply unit 124.

The compensation current supply unit 124 receives the compensation current information from the compensation current information storage unit 130 and supplies a compensation current to an operating cell according to the received compensation current amount information.

FIG. 9 is a circuit diagram illustrating a circuit configuration of a leakage current compensation device according to an exemplary embodiment of the present inventive concept. In the present embodiment illustrated in FIG. 9, a plurality of sense amplifiers are present. For example, n sense amplifiers may be present (n being an integer greater than or equal to 2). Four sense amplifies are presented in the embodiment illustrated in FIG. 9, but exemplary embodiments of the present inventive concept are not limited thereto.

In the embodiment illustrated in FIG. 9, first to fourth sense amplifiers 20, 22, 24 and 28 are present. A voltage value at one end SDL of the current supply units 110 and 10 is input to first input terminals of the first to fourth sense amplifiers 20, 22, 24, 28. First to fourth reference voltages REF0, REF1, REF2, and REF3 are input to second input terminals of the first to fourth sense amplifiers 20, 22, 24, and 28, respectively. In an embodiment, the first to fourth reference voltages REF0, REF1, REF2 and REF3 have different values to each other. However, embodiments of the present inventive concept are not limited thereto, and some reference voltage values may have the same value, as necessary.

A case, in which the first to fourth reference voltages REF0, REF1, REF2, and REF3 are preset to have different values of −1 volt, −1.5 volts, −2.5 volts and −3 volts, respectively, will be described hereinafter as an example. When a voltage value at the point SLD of the current supply unit 10 is −2.6 volts, the voltage value is lower than the first to third reference voltages REF0, REF1, and REF2 and greater than the fourth reference voltage REF3. In this case, an output value of the leakage current sensing unit 122 may be ICOMP_EN <3:0>, as illustrated in FIG. 9. When the voltage value at the SLD point of the current supply unit 10 has a certain value other than −2.5 volts to −3 volts, a result value output by the leakage current sensing unit 122 may vary. Accordingly, the result value output by the leakage current sensing unit 122 has one more than the number of reference voltages having different values, and the compensation current supply unit 124 supplies different amounts of current supply to an operating cell.

In an exemplary embodiment, the circuit of FIG. 9 includes the current supply unit 10 and a plurality of current supply units 40, 42, 44, and 46. In an embodiment, each of the current supply units includes a first transistor whose gate receives the second bias signal BIAS2 and a second transistor whose gate terminal receives an output of the first to fourth sense amplifiers 20, 22, 24, 28.

Through the embodiment illustrated in FIG. 9, the amount of leakage current may be sensed more precisely, and thus, the amount of current compensated also has various values. As a result, an appropriate amount of leakage current, corresponding to the amount of leakage current, may be supplied to an operating cell.

Also in the embodiment illustrated in FIG. 9, the magnitude of the compensation current may be determined by further reflecting a cell location and environmental elements. For example, the compensation current supply unit 124 may supply a compensation current value, considering only a location of a memory cell from the compensation current storage unit 130, a compensation current value, considering only an environmental element (temperature), or a compensation current value, considering both the location of the memory cell and the environmental element, and may reflect the supplied compensation current value on the magnitude of compensation current.

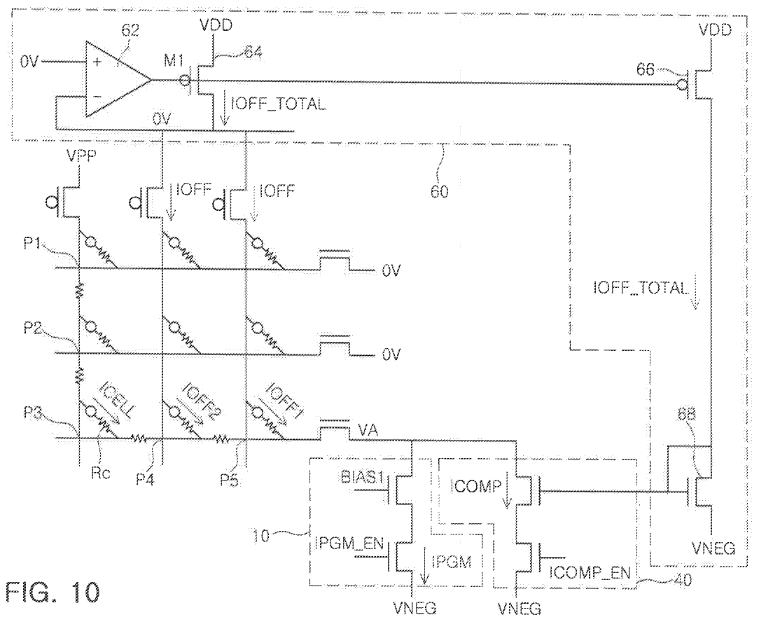

FIG. 10 is a circuit diagram illustrating a circuit configuration of a leakage current compensation device according to an exemplary embodiment of the present inventive concept. According to another example of the leakage current compensation device 100, a current supply unit 110 and a leakage current compensation unit 120 illustrated in FIG. 5 are included. The leakage current compensation unit 120 may include one of leakage current sensing units 122 and 60 and one of compensation current supply units 124 and 40. Since the leakage current supply units 110 and 10 are identical to those described with reference to FIG. 6 or FIG. 9, duplicate descriptions thereof will be omitted.

Referring to FIG. 10, the leakage current sensing units 112 and 60 may include regulator units 62 and 64 and current mirror units 66 and 68 (current mirror circuits). The regulator units 62 and 64 sense the amount of leakage current flowing to unselected bitlines except for a selected cell. The current mirror units 66 and 68 output the amount of leakage current as a result value and provide the result value to a compensation current supply unit 40. The regulator units 62 and 64 may include an amplifier 62 and a first transistor 64, and the current mirror portion 66 and 68 may include a second transistor 66 and a third transistor 68.

According to another embodiment of the leakage current compensation device of the present disclosure, information on a total IOFF_TOTAL of leakage currents IOFF1 and IOFF2 flowing to bitlines is sensed. The sensed information is provided to the compensation current supply unit 40 through a current mirror to compensate for a current. According to a related art, unselected bitlines are grounded via a switch to be connected to an unselected voltage (for example, 0 volt) and, according to at least one embodiment of the present inventive concept, unselected bitlines are connected to the regulator units 62 and 64 via a switch (not shown).

Specifically in the present embodiment, bitlines are connected to either one of a voltage VPP supplied via a switch (not shown) and an unselected voltage supplied via an input terminal of an amplifier 62. Accordingly, unselected bitlines are supplied with the unselected voltage via the input terminal of the amplifier 62, and a selected bitline is supplied with the voltage VPP via the switch (not shown). The total IOFF_TOTAL of the leakage currents IOFF1 and IOFF2 flows to the unselected bitlines flows to the first transistor 64, and is reflected on the second transistor 66 through a current mirror circuit. A current corresponding to the total IOFF_TOTAL of the leakage currents IOFF1 and IOFF2 flows to the second transistor 66 and the third transistor 68 and is ultimately transmitted to the compensation current supply unit 40.

The compensation current supply unit 40 supplies a compensation current ICOMP through information on the total IOFF_TOTAL of the received leakage currents. In this case, a determination may be made as to whether or not to perform an operation of compensating the current through a separate input signal ICOMP_EN supplied to the compensation current supply unit 40.

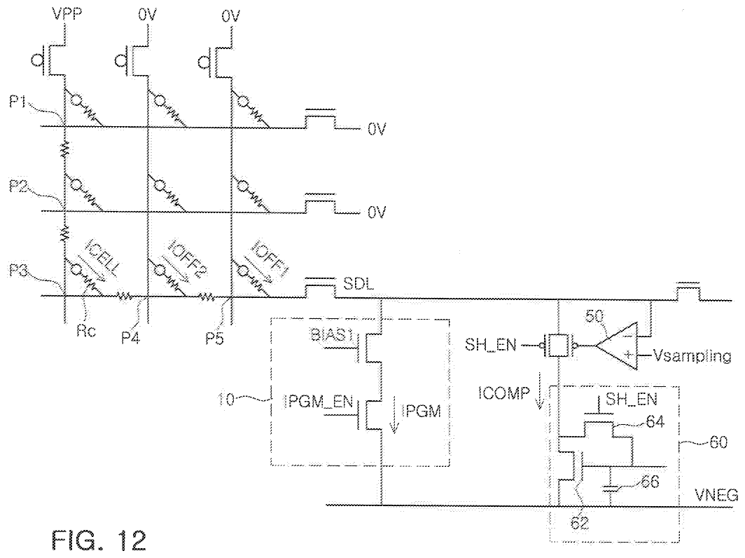

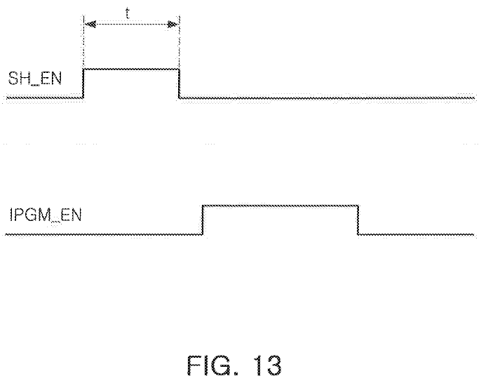

FIG. 11 is a block diagram of a leakage current compensation device according to an exemplary embodiment of the present inventive concept, FIG. 12 is a circuit diagram illustrating a circuit configuration of a leakage current compensation device according to an exemplary embodiment of the present inventive concept, and FIG. 13 is a graph illustrating an operation of the exemplary embodiment illustrated in FIG. 12.

A leakage current compensation device 200 according to an exemplary embodiment includes a current supply unit 210 (e.g., a current supply) and a leakage current compensation unit 220 (e.g., a circuit).

The current supply unit 210 has the same basic function as the current supply unit 210 in the embodiment described with reference to FIG. 5, but is different in that a current is not supplied to an operating cell during a sampling period.

The leakage current compensation unit 220 senses the amount of leakage current flowing to a non-operating cell other than operating cells, during the sampling period before an operating period, to store a result value corresponding to the sensed amount of leakage current and to supply a compensating current depending on the result value to an operating cell.

Compared with the embodiment illustrated in FIG. 5, the embodiment illustrated in FIG. 11 has a sampling period for a cell operation before the current supply unit 210 supplies a current to a memory cell. During the sampling period, the leakage current compensation unit 220 senses the amount of leakage current flowing to a non-operating cell other than operating cells. The sensing of the amount of leakage current is performed by supplying a sampling voltage, depending on a location of a cell to be operated, to one end of a current supply unit during the sampling period.

To this end, the leakage current compensation device 200 may further include a sampling voltage supply unit 230 configured to supply a different sampling voltage, depending on a cell location, to one end of the current supply unit.

The sampling voltage supply unit 230 receives location information of a cell, for example, address information, and supplies a sampling voltage depending on the location information to supply a different sampling voltage depending on the location of the cell. As described above, a voltage drop occurs due to the presence of a leakage current while supplying a current to operate a specific memory cell. Since the amount of leakage current varies depending on a location of a cell to be operated, a difference in the degree of a voltage drop occurs. As a result, a voltage applied to one end of the current supply unit 210 varies. The sampling voltage supply unit 230 receives the location information of the cell and supplies a voltage value, to be applied to the one end of the current supply unit 210 and to vary depending on the location information, to the one end of the current supply unit 210 in advance during a sampling period. The voltage value to be supplied during the sampling period may be set from a measured value or set in advance.

As described above, since the amount of the leakage current may vary depending on an environmental element, for example, a temperature variation, a memory cell may determine a sampling voltage in consideration of an influence of temperature and may supply the determined sampling voltage to one end of a current supply unit. According to another exemplary embodiment, the sampling voltage supply unit 230 may store the sampling voltage in the form of a look-up table. According to another exemplary embodiment, a temperature sensing unit 240 (e.g., a sensor or circuit) may further be provided to sense a temperature of a plurality of cells or a surrounding temperature of the plurality of cells to consider the influence of temperature. In this case, the temperature sensing unit 240 may transmit sensed temperature information to the sampling voltage supply unit 230.

The leakage current compensation unit 220 supplies the transmitted sampling voltage to one end of the current supply unit 210 in advance during the sampling period to store a result value, depending on the amount of the sensed leakage current, and supplies a compensation current, depending on the result value, to an operating cell during an operating period. This will be described below with reference to FIG. 12.

FIG. 12 shows a simplified circuit configuration according to an exemplary embodiment of the leakage current compensation device 200 illustrated in FIG. 11.

The current supply unit 210 may be connected to each wordline. In the embodiment illustrated in FIG. 12, the current supply unit 210 is described as a transistor 10 configured to conduct a current IPGM in response to an input signal IPGM_EN, but exemplary embodiments of the present inventive concept are not limited thereto.

In FIG. 12, a leakage current compensation unit 60 including a first transistor 62, a switch 64, and a capacitor 66 is provided as an example of the leakage current compensation unit 220 illustrated in FIG. 11.

The first transistor 62 passes a compensation current during an operating period. The switch 64 is connected between a drain terminal and a gate terminal of the first transistor 62. The capacitor 66 has one end, connected to the gate terminal of the first transistor 62, and the other end connected to a source terminal of the first transistor 62.

The switch 64 may be a second transistor 64, having a drain terminal and a source terminal connected to the drain terminal and the gate terminal of the first transistor 62, respectively, and the second transistor 64 receives a sampling period information signal SH_EN through a gate terminal. The gate terminal of the second transistor 64 receives ‘1’ for a sampling period and ‘0’ for a non-sampling period, as the sampling period information signal. For example, when the sampling period information signal SH_EN is ‘1’, a sampling period has begun and when the sampling period information signal SH_EN is ‘0’, the sampling period has ended.

Referring to FIG. 13, a period t representing ‘1’ in a waveform indicated by an SH_EN signal corresponds to a sampling period. When a signal input to a gate terminal of the second transistor 64 is ‘1’, a drain terminal and the gate terminal of the first transistor 62 are conducted. In this case, the first transistor 62 serves similarly to a diode. During the sampling period t, the sampling voltage supply unit 230 supplies a sampling voltage to one end SDL of the current supply unit 10. FIG. 12 illustrates an example in which a sampling voltage Vsampling is supplied through an amplifier 50, but exemplary embodiments of the present inventive concept are not limited thereto.

When the sampling voltage is supplied to an SDL terminal, a control input signal IPGM_EN supplied to the current supply unit 10 has a value ‘0’. A leakage current is expected to be generated for an operation period because a leakage potential difference occurs as the sampling voltage is supplied to the SDL terminal. For example, a sampling current flows to the source terminal through the drain terminal of the first transistor 62. A voltage value stored in a capacitor 66 varies depending on the magnitude of the sampling current. For example, when the magnitude of the sampling current is large, a value of the voltage applied to the capacitor 66 is also increased.

Then, the sampling period t is ended and the SH_EN signal becomes ‘0’. When an operating period is started, a current is supplied to a memory cell through the current supply unit 10 and a positive compensation current ICOMP corresponding to a value of a voltage applied to the capacitor 66 passes through the first transistor 62. For example, the amount of compensation current compensated by the first transistor 62 is determined depending on the magnitude of the voltage applied to a gate-source terminal of the first transistor 62.

In another embodiment, information on the amount of leakage current, generated in the state in which the sampling voltage supply unit 230 does not supply a sampling voltage to one end SDL of a current supply unit during a sampling period, may be determined. In other words, a state in which an unselected voltage (for example, 0 volt) is applied to all bitlines and all wordlines of a semiconductor memory device, for example, a state in which no cell operates is set, and information on how much a leakage current is generated in a corresponding semiconductor memory device is stored in a leakage current compensation unit 220.

The leakage current compensation unit 220 may include a latch circuit configured to store information on a leakage current. The latch circuit may include a first transistor 62. A configuration of a leakage current compensating section 60 including a switch 64 and a capacitor 66 may be applied as an example of the latch circuit. For example, the information on the leakage current may be stored as a value of a voltage applied to the capacitor 66 of the leakage current compensator 60, and then a compensation current supply amount may be determined. In this case, a period in which the SH_EN signal is ‘1’, shown in FIG. 13, may further include a period in which a sampling voltage is not supplied, besides a period in which the sampling voltage is supplied to one end SDL of the current supply unit. Information on a leakage current, collected during the period in which the sampling voltage is not supplied (for example, the amount of leakage current generated), may be used to determine the compensation current ICOMP corresponding to the leakage current generated when the SH_EN signal becomes ‘0’ and a current is supplied to a memory cell to be operated by applying a control input signal IPGM_EN to the current supply unit 10.

The present inventive concept relates to a semiconductor memory device which supplies a current to a memory cell to be operated, among a plurality of memory cells disposed at intersections of a plurality of wordlines and a plurality of bitlines, and senses the amount of leakage current flowing to a non-operating cell, other than operating cells, to supply a compensation current to an operating cell according to the sensed amount of leakage current. The semiconductor memory device includes a current supply portion connected to one end of at least one wordline, among the plurality of wordlines, to supply a current to at least one of the plurality of memory cells and a leakage current compensation unit configured to sense the amount of leakage current flowing to a non-operating cell other than operating cells to supply a compensation current to the operating cell according to the sensed amount of leakage current. The leakage current compensation unit may employ the leakage current compensation units 120 and 220 described in FIGS. 5 and 11, and detailed description thereof will be omitted to avoid duplicate description.

In the description, the term “unit,” “module,” “table,” or the like may refer to a software component or hardware component such as a field programmable gate array (FPGA) or an application specific integrated circuit (ASIC), and a module performs some functions. However, a module is not limited to hardware or software. A module may be configured to reside in an addressable storage medium or to drive one or more processors. Modules may refer to software components, object-oriented software components, class components, task components, processes, functions, attributes, procedures, subroutines, program code segments, drivers, firmware, microcode, circuits, data, databases, data structures, tables, arrays or variables. A function provided by a component and a module may be a combination of smaller components and modules, and may be combined with others to compose large components and modules. Components and modules may be configured to drive one or more central processing units (CPUs) in components and modules.

As described above, at least one exemplary embodiment of the present inventive concept provides a semiconductor memory sensing a leakage current and compensating for the leakage current. The leakage current may be generated when an operation is performed on a specific cell among a plurality of cells present in a semiconductor memory. The amount of compensation may adaptively vary based on a cell location and/or a surrounding environment.

While exemplary embodiments have been shown and described above, it will be apparent to those skilled in the art that modifications and variations can be made without departing from the scope of the present inventive concept.

What is claimed is:

1. A leakage current compensation device comprising:
a current supply unit configured to supply a current to at least one operating cell, among a plurality of cells of a memory device disposed at intersections of wordlines and bitlines;
a leakage current sensing unit configured to sense an amount of leakage current flowing to a non-operating cell among the cells to output a result value based on the sensed amount of leakage current; and
a compensation current supply unit configured to receive the result value and supply a compensation current to the operating cell.

2. The leakage current compensation device of claim 1, wherein the leakage current sensing unit includes a first sense amplifier configured to sense a voltage value at one end of the current supply unit.

3. The leakage current compensation device of claim 2, wherein the voltage value at the one end of the current supply unit is supplied to a first input terminal of the first sense amplifier, a first reference voltage is supplied to a second input terminal of the first sense amplifier, and the first sense amplifier compares the voltage value at the one end of the current supply unit with the first reference voltage to output the result value.

4. The leakage current compensation device of claim 1, wherein the leakage current sensing unit includes first to n-th sense amplifiers configured to sense the voltage value at the one end of the current supply unit, where n is an integer greater than or equal to 2.

5. The leakage current compensation device of claim 4, wherein the voltage value at the one end of the current supply unit is supplied to a first input terminal of each of the first to n-th sense amplifiers, and
first to nth reference voltages, different from each other, are supplied to a second input terminal of each of the first to n-th sense amplifiers.

6. The leakage current compensation device of claim 5, wherein the leakage current sensing unit compares the voltage value at the one end of the current supply unit with the respective first to n-th reference voltages to output different result values.

7. The leakage current compensation device of claim 1, further comprising:
a storage unit configured to store different compensation current information depending on at least one of different temperature intervals and different cell locations.

8. The leakage current compensation device of claim 7, further comprising:
a temperature sensing unit configured to sense a temperature of the plurality of cells or a surrounding temperature of the plurality of cells to generate sensed temperature information,
wherein the temperature sensing unit transmits the sensed temperature information to the storage unit.

9. The leakage current compensation device of claim 7, wherein the compensation current supply unit receives the compensation current information and supplies a compensation current to the operating cell according to the received compensation current information.

10. The leakage current compensation device of claim 1, wherein the leakage current sensing unit comprises:
a regulator unit configured to sense the amount of leakage current flowing to the unselected bitlines which do not include a selected cell; and
a current mirror unit configured to output the amount of the leakage current to the compensation current supply unit as the result value.

11. The leakage current compensation device of claim 10, wherein the regulator unit comprises:
an amplifier configured to provide an unselected voltage to the unselected bitlines; and
a first transistor to which a current corresponding to a total value of leakage currents flowing to the unselected bitlines flows.

12. A leakage current compensation device comprising:
a current supply unit configured to supply a current to at least one operating cell, among a plurality of cells of a memory device disposed at intersections of wordlines and bitlines; and
a leakage current compensation unit configured to sense an amount of leakage current flowing to a non-operating cell among the cells during a sampling period before an operating period to determine a result value based on the sensed amount of leakage current and to supply a compensation current to the operating cell based on the result value during the operating period.

13. The leakage current compensation device of claim 12, further comprising:
a sampling voltage supply unit configured to supply a different sampling voltage based on a cell location, to one end of the current supply unit.

14. The leakage current compensation device of claim 12, further comprising:
a sampling voltage supply unit configured to supply a different sampling voltage based on a cell location and different temperature intervals, to one end of the current supply unit.

15. The leakage current compensation device of claim 14, further comprising:
a temperature sensing unit configured to sense a temperature of the plurality of cells or a surrounding temperature of the plurality of cells to generate sensed temperature information,
wherein the temperature sensing unit transmits the sensed temperature information to the sampling voltage supply unit.

16. The leakage current compensation device of claim 12, wherein the leakage current compensation unit comprises:
a first transistor through which the compensation current passes;
a switch configured to connect a drain terminal of the first transistor and a gate terminal of the first transistor to each other; and
a capacitor configured to connect the gate terminal of the first transistor and a source terminal of the first transistor to each other.

17. The leakage current compensation device of claim 16, wherein the switch is a second transistor configured to receive a sampling period information signal through a gate terminal of the second transistor, and
a drain terminal of the second transistor and a source terminal of the second transistor are connected to the drain terminal of the first transistor and the gate terminal of the first transistor, respectively.

18. The leakage current compensation device of claim 17, wherein the sampling period information signal is a digital signal which is 1 during the sampling period and 0 outside the sampling period.

19. The leakage current compensation device of claim 16, wherein the capacitor stores the result value based on the amount of leakage current sensed during the sampling period, as a voltage value.

20. A semiconductor memory device comprising:
a plurality of memory cells disposed at intersections of a plurality of wordlines and a plurality of bitlines;
a current supply unit connected to one end of at least one wordline among the plurality of wordlines to supply a current to at least one operating cell among the plurality of memory cells; and
a leakage current compensation unit configured to sense an amount of leakage current flowing to a non-operating cell of the memory cells to supply a compensation current to the operating cell according to the sensed amount of leakage current.
